(19) United States
(12) Patent Application Publication
(10) Pub. No.: US 2013/0199719 A1
(43) Pub. Date: Aug. 8, 2013

(54) DRAWING APPARATUS, AND METHOD OF MANUFACTURING ARTICLE

(71) Applicant: CANON KABUSHIKI KAISHA, Tokyo (JP)

(72) Inventors: Go TSUCHIYA, Tochigi-shi (JP); Tomoyuki MORITA, Utsunomiya-shi (JP)

(73) Assignee: CANON KABUSHIKI KAISHA, Tokyo (JP)

(21) Appl. No.: 13/754,216

(22) Filed: Jan. 30, 2013

(30) Foreign Application Priority Data
Feb. 6, 2012 (JP) 2012-023506

(51) Int. Cl. H01J 37/30

(52) U.S. Cl. CPC H01J 37/3007
USPC 156/272.2; 250/396 R; 427/145; 264/485

(57) ABSTRACT

A drawing apparatus which performs drawing on a substrate with a plurality of charged particle beams includes: a blanking device configured to individually blank the plurality of charged particle beams; a scanning deflector configured to deflect the plurality of charged particle beams to scan the plurality of charged particle beams on the substrate; and a controller configured to generate a periodic signal to control a periodic deflection operation of the plurality of charged particle beams by the scanning deflector. The controller is configured to adjust an amount of deflection of the plurality of charged particle beams by the scanning deflector in a period of the periodic signal so that a scanning speed of the plurality of charged particle beams becomes a target speed.

### BACKGROUND OF THE INVENTION

1. Field of the Invention

The present invention relates to a drawing apparatus which performs drawing on a substrate with a plurality of charged particle beams, and a method of manufacturing an article.

2. Description of the Related Art

In an electron beam drawing apparatus (electron beam exposure apparatus) employed to manufacture a semiconductor integrated circuit, miniaturization of elements in a semiconductor integrated circuit, an increase in complexity of a circuit pattern, and an increase in the size of pattern data has progressed in recent years, and a demand to improve not only the drawing precision but also the throughput has arisen. To meet this demand, a raster electron beam drawing apparatus which performs raster deflection of a plurality of electron beams at once, and performs drawing upon simultaneously, independently turning on and off the plurality of electron beams in the exposure portion and non-exposure portion of a substrate to draw an arbitrary pattern is available. This drawing apparatus performs raster deflection at once so as to perform drawing in an area corresponding to the product of the deflection range and the number of electrons, thus improving the throughput.

Japanese Patent Laid-Open No. 1-107533 discloses a method of adjusting the deflection speed of a raster deflector in order to perform drawing on a substrate at a desired dose (in a desired exposure amount) in an electron beam drawing apparatus. Japanese Patent Laid-Open No. 2006-86182 discloses a method of performing drawing on a substrate upon ON/OFF control of a plurality of electron beams based on multilevel drawing data. A raster multi-electron beam drawing apparatus performs ON/OFF control of each electron beam and deflector control for raster deflection based on a synchronous clock signal.

In drawing based on multilevel drawing data, the ratio between the ON and OFF times of each electron beam in one clock period of a synchronous clock signal, that is, the duty ratio is changed in accordance with the numerical value of the drawing data. At this time, the ON/OFF time of each electron beam is implemented upon, for example, the following steps 1 to 4. In step 1, a blanking clock signal is generated by multiplying or dividing a synchronous clock signal using, for example, a PLL (Phase Locked Loop) circuit. In step 2, a blanking signal is generated by, for example, counting generated blanking clock signals in correspondence with the numerical value of the drawing data. In step 3, the blanking signal is transferred to a blanking deflector serving as an electrostatic deflection electrode. In step 4, the ON/OFF time is adjusted by electrostatically deflecting the electron beam by the blanking deflector. If the numerical value of the drawing data is, for example, zero, the electron beam is kept OFF for one clock period of the synchronous clock signal. However, if the numerical value of the drawing data is close to a maximum value, the electron beam is kept ON for most of one clock period of the synchronous clock signal.

A raster deflector signal to be input to a raster deflector is generally output from a deflector amplifier. A signal to be input to the deflector amplifier is output from a digital-to-analog converter (DAC) which constitutes part of a deflector signal control circuit. Hence, the deflection speed of the raster deflector can be adjusted by adjusting the update period of a signal output from the digital-to-analog converter (DAC). The signal output from the digital-to-analog converter (DAC) is typically updated at timings defined by a raster deflector clock signal. A raster deflector clock signal is generated by multiplying or dividing a synchronous clock signal used in the overall control system of the electron beam drawing apparatus. Hence, the update period of a signal output from the digital-to-analog converter (DAC) can be changed by changing the period of an original, synchronous clock signal.

In a raster electron beam drawing apparatus, the variation in ON/OFF control timing of all electron beams must fall within a tolerance. When the variation in timing is large, a settling time to absorb this variation must be set separately, thus making it impossible to improve the drawing throughput. Also, when the raster deflector signal has a perfect ramp waveform or a waveform close to it, drawing is performed at an erroneous position on the substrate. The variation in timing occurs because, for example, a variation occurs in line length upon manufacture or design between a plurality of blanking deflectors and a blanking control circuit which generates a blanking signal. Upon the occurrence of a variation in time for the blanking signal to reach the blanking deflector, a variation in ON/OFF control timing of each electron beam occurs. This makes it necessary to perform adjustment for reducing the variation in ON/OFF control timing of each electron beam. The following description assumes that the variation in timing is that in time for the blanking signal to reach the blanking deflector.

Methods of rough adjustment for the variation in time for the blanking signal to reach the blanking deflector include a method of adjustment for each clock period of a blanking clock signal by, for example, delaying the count start timing of blanking clock signals in the blanking control circuit in accordance with individual blanking signals is available. Methods of fine adjustment for this variation include a method of adjusting the length of a cable line between the blanking control circuit and the blanking deflector, and a method of arranging a plurality of delay elements and a plurality of bypass lines for the delay elements on individual blanking signal lines to change the number of blanking signals which pass through the delay elements. Although a method of adjusting the variation in time for the blanking signal to reach the blanking deflector is complex, this variation must be adjusted at least once in the period of a synchronous clock signal used in an electron beam drawing apparatus to avoid the above-mentioned problem. The case wherein the period of a synchronous clock signal is changed will be considered next. Since the period of a synchronous clock signal is changed, the count start timing to be controlled in a rough adjustment method must also be changed in accordance with individual blanking signals. As a result of rough adjustment, fine adjustment becomes necessary as well. In the fine adjustment method, it is difficult to physically change the length of a cable line, thus making it necessary to perform adjustment for, for example, changing the number of blanking signals which pass through the delay elements. These types of adjustment must be done so that the variation in time for the blanking signal to reach the blanking deflector falls within a tolerance in the change range of the period of a synchronous clock signal.

Especially in the recent raster multi-electron beam drawing apparatus, the number of electron beams is increasing to several ten thousand to several million electron beams in order to further improve the throughput. This amounts to increasing the number of blanking deflectors to several ten thousand to several million blanking deflectors. As a result, the number of lines for blanking signals becomes very large, so an operation of adjusting the variation in time for the blanking signal to reach the blanking deflector becomes very complex, thus prolonging the adjustment time. Further, when the period of a synchronous clock signal is changed, adjustment in the change range becomes necessary, thus increasingly prolonging the adjustment time. It is also probable that the arrangement pitch of blanking deflectors which turn on/off electron beams cannot be set as narrow as that in the conventional electron beam drawing apparatus due to problems associated with design or manufacture. In this case, as the number of blanking deflectors increases, the size of a blanking deflector array formed by blanking deflectors also increases. As a result, the difference in line length of blanking signals connected to individual blanking deflectors becomes larger, so an operation of adjusting the variation in time for the blanking signal to reach the blanking deflector becomes very complex, thus prolonging the adjustment time. Further, when the period of a synchronous clock signal is changed, the adjustment time increasingly prolongs, as described above.

### SUMMARY OF THE INVENTION

The present invention provides, for example, a drawing apparatus advantageous in change of a scanning speed of a plurality of charged particle beams.

The present invention provides a drawing apparatus which performs drawing on a substrate with a plurality of charged particle beams, the apparatus comprising: a blanking device configured to individually blank the plurality of charged particle beams; a scanning deflector configured to deflect the plurality of charged particle beams to scan the plurality of charged particle beams on the substrate; and a controller configured to generate a periodic signal to control a periodic deflection operation of the plurality of charged particle beams by the scanning deflector, wherein the controller is configured to adjust an amount of deflection of the plurality of charged particle beams by the scanning deflector in a period of the periodic signal so that a scanning speed of the plurality of charged particle beams becomes a target speed.

Further features of the present invention will become apparent from the following description of exemplary embodiments with reference to the attached drawings.

### BRIEF DESCRIPTION OF THE DRAWINGS

FIG. 1 is a view showing the configuration of a raster electron beam drawing apparatus;

FIG. 2 shows views of a raster drawing method which uses electron beams;

FIG. 3 is a timing chart according to the first embodiment;

FIG. 4 is a flowchart showing the sequence of calculation of the deflection speed;

FIGS. 5A and 5B are views for explaining the case wherein the pixel density of drawing data is double a reference pixel density in the first embodiment;

FIG. 6 is a timing chart when the deflection speed conversion coefficient is ½ in the first embodiment;

FIGS. 7A and 7B are timing charts when the resist sensitivity and/or minimum current density has changed, and the deflection speed conversion coefficient is ½ in the first embodiment;

FIGS. 8A and 8B are graphs showing the cumulative dose distributions of electron beams according to the conventional technique and the present invention, respectively, when the resist sensitivity and/or minimum current density has changed in the first embodiment; and

FIG. 9 is a timing chart when a raster deflector clock signal is obtained by multiplying a synchronous clock signal by a factor of four in the second embodiment.

### DESCRIPTION OF THE EMBODIMENTS

Embodiments of the present invention will be described below with reference to the accompanying drawings. Although the present invention is applicable to a drawing apparatus which draws a pattern on a substrate with a plurality of charged particle beams such as electron beams or ion beams, an example in which the present invention is applied to a raster drawing apparatus which draws a pattern on a substrate with a plurality of electron beams will be described.

### First Embodiment

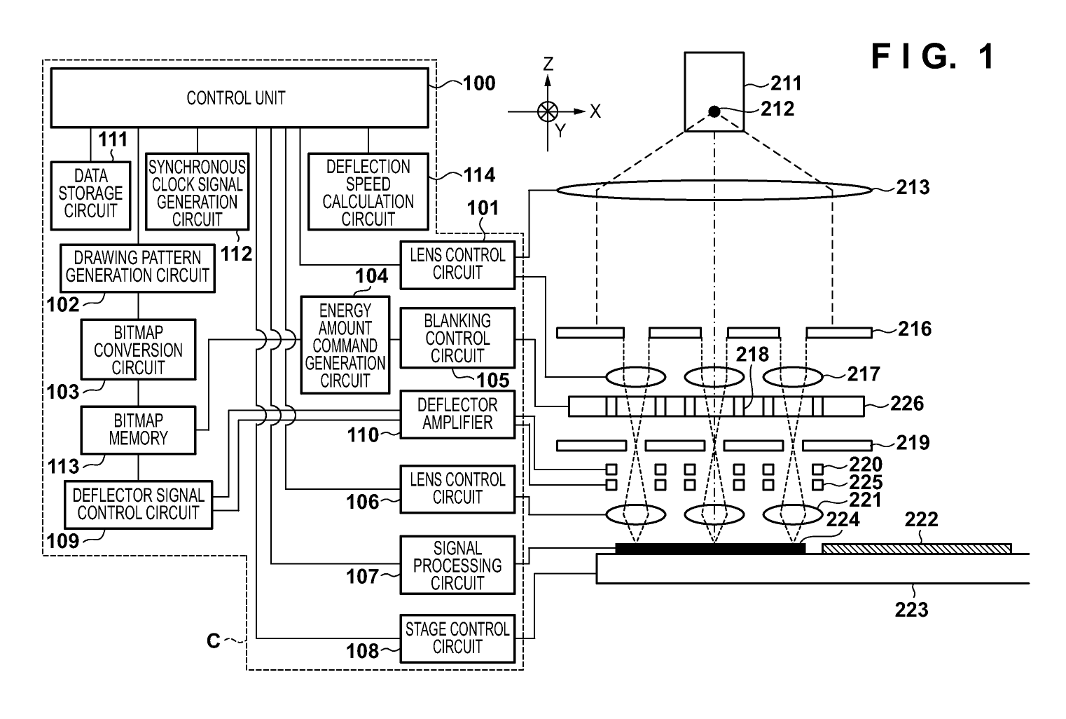

FIG. 1 is a view showing the configuration of a raster drawing apparatus which draws a pattern on a substrate with a plurality of electron beams according to the first embodiment of the present invention. An electron gun 211 forms a crossover image 212. A diverging electron beam from the crossover image 212 is converted into a collimated beam by the action of a collimator lens 213 implemented by an electromagnetic lens, and enters an aperture array 216. The aperture array 216 includes a plurality of circular apertures arrayed in a matrix, and splits the incident electron beam into a plurality of electron beams. The electron gun 211, collimator lens 213, and aperture array 216 constitute a generation unit which generates a plurality of electron beams.

The electron beams having passed through the aperture array 216 enter an electrostatic lens 217 formed by three electrodes (electrode members or electrode plates; these electrodes are shown as an integrated electrode in FIG. 1) including circular apertures. Blanking apertures 219 having openings arrayed in a matrix are arranged at the positions at which the electrostatic lens 217 forms crossover images for the first time. A plurality of electron beams are individually blanked by blanking deflectors (blanking devices) 218 arranged in a blanking deflector array 226 in a matrix, and are individually turned on/off by the blanking apertures 219. The blanking deflectors 218 are controlled by a blanking control circuit 105. The blanking control circuit 105 is controlled by signals generated by a drawing pattern generation circuit 102, bitmap conversion circuit 103, bitmap memory 113, and energy amount command generation circuit 104. The bitmap memory 113 stores drawing data converted into bitmap data by the bitmap conversion circuit 103. The blanking deflectors 218, blanking apertures 219, and blanking control circuit 105, for example, constitute a blanking unit.

The electron beams having passed through the blanking apertures 219 are focused by an electrostatic lens 221 to form original crossover images 212 on an electron beam detection unit 224 or a substrate 222 such as a wafer or a mask. While a pattern is drawn on the substrate 222, the substrate 222 is continuously scanned in the Y-direction by a stage 223, so light which bears the information of the image on the substrate 222 is deflected in the X-direction by a raster deflector (scanning deflector) 220 with reference to the distance measurement result obtained for the stage 223. At the same time, light which bears the information of the image on the substrate 222 is deflected by a stage following deflector 225 so as to follow stage movement in the Y-direction, that is, the stage scanning direction. The electron beams are turned on/off at timings required for drawing by the blanking deflectors 218. The raster deflector 220 and stage following deflector 225 are controlled in accordance with a raster deflector signal and a stage following deflector signal which are generated by a deflector signal control circuit 109 and transferred via a deflector amplifier 110. The stage 223 is controlled by a stage control circuit 108. A digital-to-analog conversion circuit (DAC) is formed in the output stage of the deflector signal control circuit 109.

A signal processing circuit 107 detects a signal (output) from the electron beam detection unit 224, and processes it. The use of the electron beam detection unit 224 also allows measurement of the current density of each electron beam on the substrate 222. A lens control circuit 101 controls the collimator lens 213 and electrostatic lens 217, and a lens control circuit 106 controls the electrostatic lens 221. Also, a control unit 100 controls the overall drawing operation. A data storage circuit 111 stores various types of data used in, for example, a drawing operation under the control of the control unit 100 as a whole, and data associated with, for example, various control circuits. A synchronous clock signal generation circuit 112 generates an original, synchronous clock signal used to synchronize the various control circuits of the drawing apparatus with each other. A deflection speed calculation circuit 114 obtains the information of the resist sensitivity of the substrate 222 obtained, the information of the current density of each electron beam on the substrate 222, and the information of the pixel density of the drawing data stored in the bitmap memory 113, all via the control unit 100. The deflection speed calculation circuit 114 uses at least one of the obtained pieces of information to determine the deflection speed of the raster deflector 220 (the scanning speed of each electron beam). The control unit 100, deflection speed calculation circuit 114, and various control circuits, for example, constitute a controller C which controls the drawing operation of the drawing apparatus.

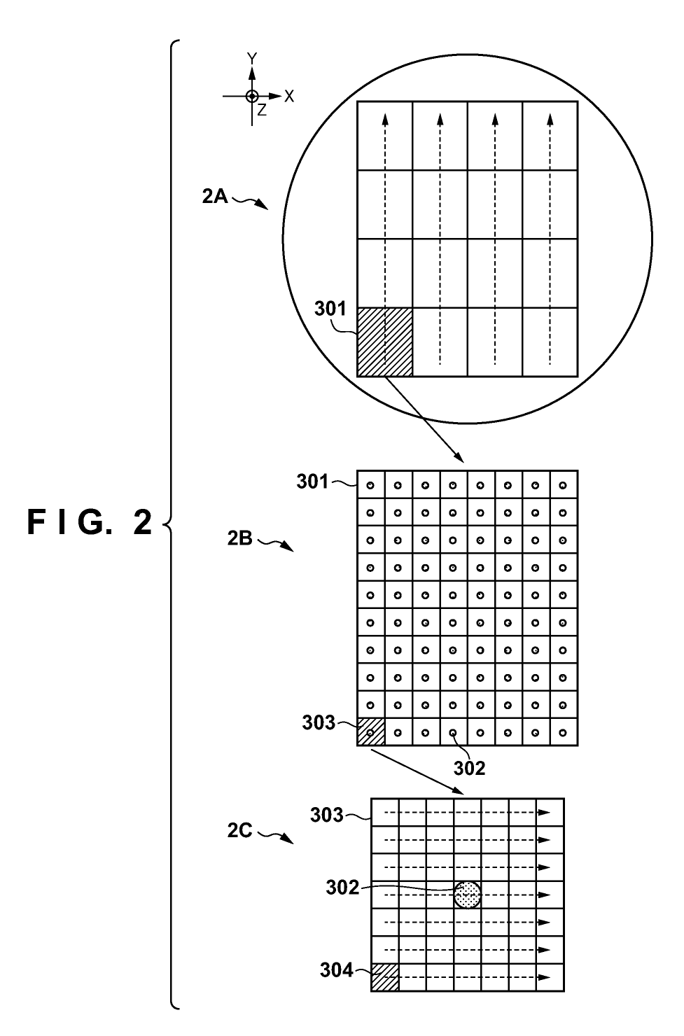

FIG. 2 shows views of a raster drawing method which uses a plurality of electron beams. As shown in 2A of FIG. 2, a pattern to be drawn on the substrate 222 is drawn upon being divided into main fields 301. The main field 301 coincides with a chip size of about 26 mm×33 mm. As shown in 2B of FIG. 2, in the main field 301, an electron beam 302 is deflected on the substrate 222 by the raster deflector 220 and stage following deflector 225 to perform drawing on the entire surface of the main field 301. Although 2B in FIG. 2 shows the case wherein 64 electron beams are used, several ten thousand to several million electron beams are used in practice. As shown in 2C of FIG. 2, the region of the main field 301, in which drawing is performed with one electron beam, is a microfield 303.

In the microfield 303, the raster deflection operation of the electron beam 302 is performed sequentially from the lower left corner upon defining, as a unit, a pixel 304 having nearly the same size as that of the electron beam 302. All electron beams in the main field 301 are collectively deflected and scanned by the raster deflector 220 and stage following deflector 225. By adjusting the duty ratio between ON and OFF of the electron beam in synchronism with the deflection operation for each pixel, a pattern is drawn in the main field 301. Also, bitmap drawing data basically corresponds to the information of the duty ratio for each pixel, and is stored in the bitmap memory 113.

After the drawing operation of one main field is completed, the stage performs step movement in an amount corresponding to the main field. The drawing operation of the next main field is also performed using the above-mentioned drawing method. At this time, the stage continuously moves during the drawing operation of one main field. The size of each field is as follows: each pixel has a size of 16 nm×16 nm, each microfield has a size of 2 μm×2 μm, and each main field has a size of 26 mm×33 mm.

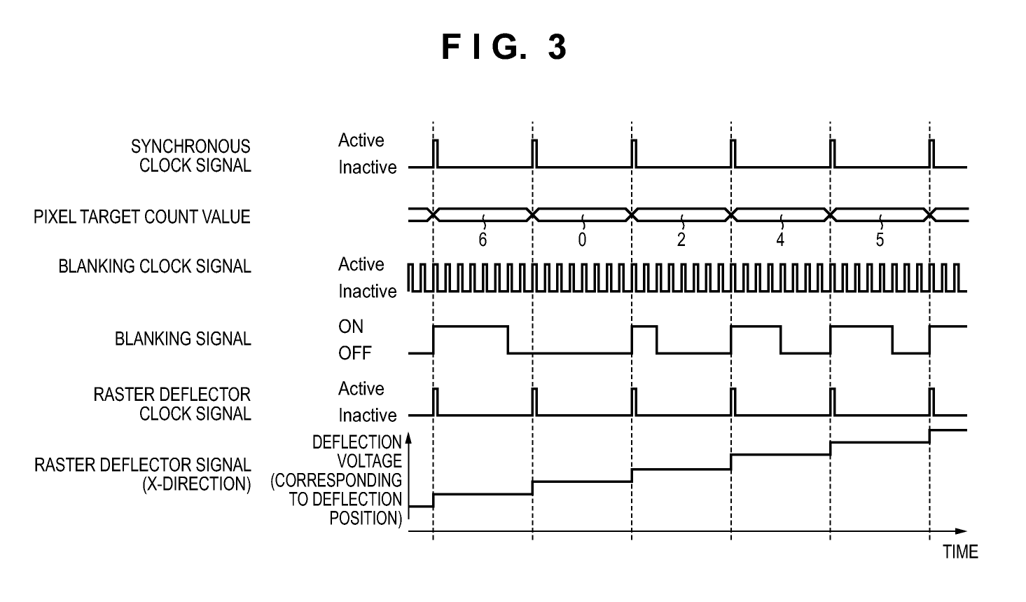

A timing chart of a synchronous clock signal, blanking clock signal, blanking signal, raster deflector clock signal, and raster deflector signal during the raster deflection operation will be described below. FIG. 3 is a timing chart. The abscissa of FIG. 3 corresponds to time for all the signals. The ordinate of FIG. 3 indicates the signal Active/Inactive state for the synchronous clock signal, blanking clock signal, and raster deflector clock signal. The pixel target count value is a numerical value associated with drawing data, and corresponds to the duty ratio of ON and OFF of the electron beam. The blanking signal indicates a command voltage applied to the blanking deflector, and corresponds to the ON/OFF timing of the electron beam. The raster deflector signal indicates a deflection voltage applied to the raster deflector 220, and corresponds to the deflection position on the substrate 222. The raster deflector signal is a periodic signal generated by the DAC in order to control the periodic deflection operations of a plurality of electron beams by the raster deflector 220. As shown in FIG. 3, when the deflection voltage intermittently changes over a plurality of predetermined periods, the scanning speed of the electron beam can be determined as the average speed between these periods.

Referring to FIG. 3, the blanking clock signal is obtained by multiplying the synchronous clock signal by a factor of eight. If the pixel target count value is seven, the electron beam is kept ON for most of one period of the synchronous clock signal, that is, the duty ratio is 87.5% (=7/8×100(%)). If the pixel target count value is zero, the electron beam is kept OFF, that is, the duty ratio is 0% (=0/8×100(%)). If the pixel target count value is four, the electron beam is kept ON and OFF for the same period of time, that is, the duty ratio is 50% (=4/8×100(%)). The blanking signal is output by so-called PWM control. Referring to FIG. 3, the raster deflector signal is in phase with the synchronous clock signal. The raster deflector signal is updated at the Active timing of the raster deflector clock signal.

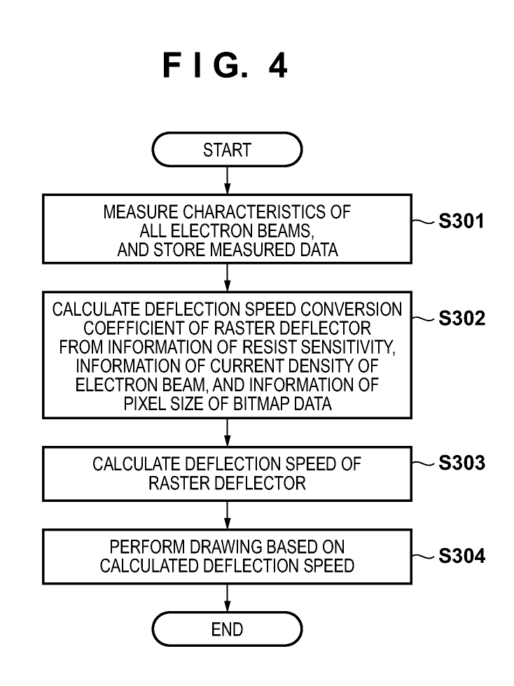

The sequence of calculation of the deflection speed will be explained below. FIG. 4 is a flowchart showing the sequence of calculation of the deflection speed. To draw a desired pattern on the substrate 222, it is necessary to determine not only the duty ratio between ON and OFF of the electron beam but also at least one of three pieces of information: the resist sensitivity of the substrate 222, the current density of the electron beam, and the pixel density of the drawing data.

In step S301, the control unit 100 uses the electron beam detection unit 224 to measure the characteristics of all electron beams. The control unit 100 obtains current densities J (A/cm²) of all electron beams on the substrate 222 from the output of the electron beam detection unit 224, and the calculation process result obtained by the signal processing circuit 107. The control unit 100 stores the information of the current densities J of all electron beams in the data storage circuit 111.

In step S302, the deflection speed calculation circuit 114 calculates a deflection speed conversion coefficient α of the raster deflector 220. The deflection speed calculation circuit 114 obtains the information of a resist sensitivity D (C/cm²) of the substrate 222 via the control unit 100. The deflection speed calculation circuit 114 also obtains the information of a minimum current density Jmin among the current densities of all electron beams via the control unit 100. The deflection speed calculation circuit 114 moreover obtains the information of a pixel density Pdata (Pixel/cm²) of the drawing data, stored in the bitmap memory 113, via the control unit 100. The deflection speed calculation circuit 114 then calculates a maximum irradiation time Tmax (sec) in a certain pixel on the substrate 222 in accordance with:

Tmax=D/Jmin (1)

The deflection speed calculation circuit 114 obtains a period Tclk (sec) of the synchronous clock signal via the control unit 100. The deflection speed calculation circuit 114 also obtains a reference pixel density Pinit (Pixel/cm²). The deflection speed calculation circuit 114 then calculates the deflection speed conversion coefficient α of the raster deflector 220 in accordance with:

α=(Tclk/Tmax)×(Pinit/Pdata) (2)

In step S303, the deflection speed calculation circuit 114 calculates the deflection speed of the raster deflector 220 during drawing in the main field 301. The deflection speed calculation circuit 114 obtains a reference pixel size Lx (nm) of drawing data unique to the drawing apparatus in the raster deflection direction via the control unit 100. The deflection speed calculation circuit 114 also obtains the information of the period Tclk (sec) of the synchronous clock signal. The deflection speed calculation circuit 114 then calculates a reference deflection speed Vinit (mm/sec) of the raster deflector 220 in accordance with:

Vinit=Lx/Tclk×(10⁻⁶) (3)

A reference pixel size Ly (nm) in the stage scanning direction generally satisfies:

Lx=Ly (4)

Using the deflection speed conversion coefficient α calculated in step S302, the deflection speed calculation circuit 114 calculates a deflection speed (target speed) Vnew (mm/sec) of the raster deflector 220 during drawing of the substrate 222 in accordance with:

Vnew=α×Vinit (5)

The deflection speed conversion coefficient α serves to adjust the amount of deflection of the electron beam in each period of the raster deflector signal while keeping the period constant, so that the deflection speed of the electron beam becomes the target speed. A large deflection speed conversion coefficient α acts in the direction to raise the deflection speed, while a small deflection speed conversion coefficient α acts in the direction to lower the deflection speed.

In step S304, the control unit 100 controls the overall apparatus so as to perform drawing on the substrate 222 at the deflection speed Vnew of the raster deflector 220.

In the above-mentioned equation (5), the deflection speed conversion coefficient α is used to calculate the deflection speed Vnew (mm/sec) of the raster deflector 220 during drawing. However, with the above-mentioned method, the deflection speed Vnew of the raster deflector 220 can also be calculated without using the deflection speed conversion coefficient α. The reference pixel density Pinit (Pixel/cm²) and the reference pixel sizes Lx and Ly (nm) satisfy a relation:

Pinit=1/(Lx×Ly)×(10¹⁴) (6)

The deflection speed calculation circuit 114 can obtain the pixel size of the drawing data, stored in the bitmap memory 113, via the control unit 100. The pixel density Pdata (Pixel/cm²) of the drawing data is given by:

Pdata=1/(Lx_new×Ly)×(10¹⁴) (7)

where Lx_new (nm) is the pixel size in the raster deflection direction, and Ly (nm) is the pixel size in the stage scanning direction and is equal to the reference pixel size.

Hence, from equations (2), (3), (5), (6), and (7), the deflection speed Vnew (mm/sec) of the raster deflector 220 during drawing on the substrate 222 can be calculated in accordance with:

Vnew=Lx_new/Tmax×(10⁻⁶) (8)

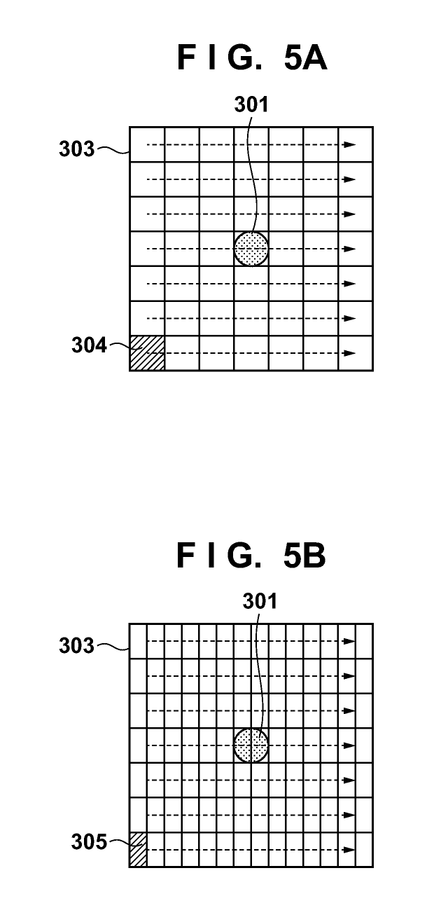

The case wherein the pixel density Pdata has changed from the reference pixel density Pinit by a factor of two will be described below with reference to the above-mentioned steps shown in FIG. 4. At this time, the period Tclk of the synchronous clock signal coincides with the maximum irradiation time Tmax. FIGS. 5A and 5B are views showing the case wherein the pixel density Pdata of the drawing data is double the reference pixel density Pinit. Also, FIGS. 5A and 5B show the microfield 303 in which drawing is performed with one electron beam. FIG. 5A shows the size of the pixel 304 at the reference pixel density Pinit, and FIG. 5B shows the size of a pixel 305 when the pixel density Pdata is double the reference pixel density. In the process of the above-mentioned steps shown in FIG. 4, the deflection speed conversion coefficient α is calculated as ½. As a result, the deflection speed Vnew of the raster deflector 220 is half the reference deflection speed Vinit unique to the drawing apparatus.

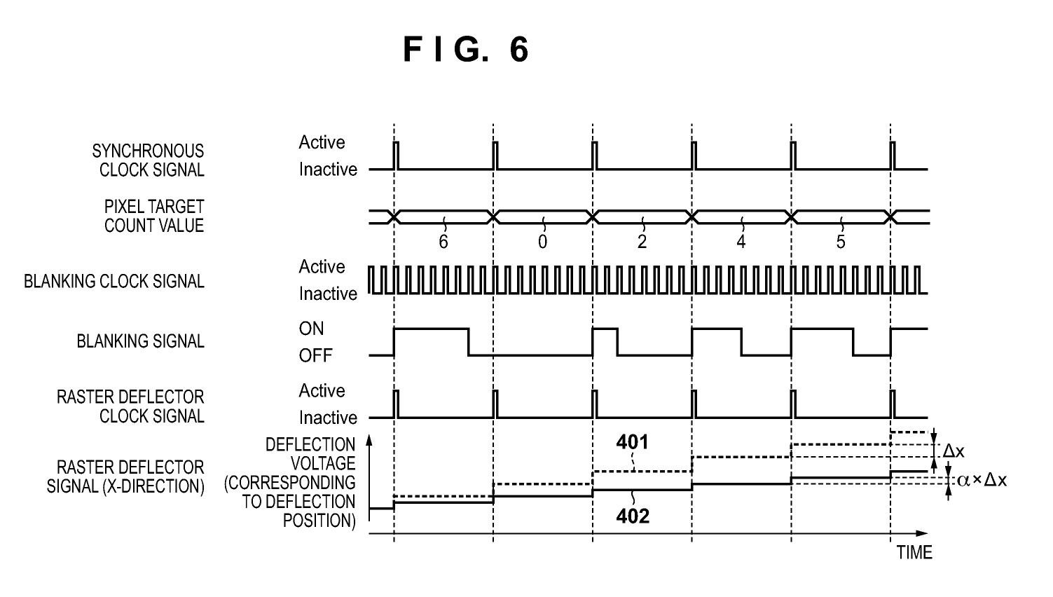

FIG. 6 is a timing chart when the deflection speed conversion coefficient α is ½. The definition of the coordinate axes in FIG. 6 is the same as in FIG. 3. In the raster deflector signal shown in FIG. 6, a dotted line 401 indicates an operation at the reference deflection speed Vinit, and a solid line 402 indicates an operation at the deflection speed Vnew. As can be seen from FIG. 6, the deflection speed has halved. Also, as shown in FIG. 6, even if the reference deflection speed Vinit and the deflection speed Vnew are different from each other, the period of the synchronous clock signal, that of the blanking signal, and that of the raster deflector clock signal remain constant and need not be changed. The deflection speed of the raster deflector 220 is adjusted by multiplying the amount of change in deflection voltage by a factor of α at the time of updating the raster deflector signal. The target value of the deflection voltage at the time of updating the raster deflector signal is calculated by the deflector signal control circuit 109. This obviates the need for a complex operation of adjusting the variation in time for the blanking signal to reach the blanking deflector upon a change in period of the synchronous clock signal.

The case wherein the resist sensitivity D (and/or minimum current density Jmin) has changed will be described with reference to the above-mentioned sequence shown in FIG. 4. At this time, the pixel density Pdata is equal to the reference pixel density Pinit. In the process of the sequence shown in FIG. 4, the maximum irradiation time Tmax is calculated. Assume that the maximum irradiation time Tmax is calculated as a value double the period Tclk of the synchronous clock signal. As a result, the deflection speed conversion coefficient α is calculated as ½.

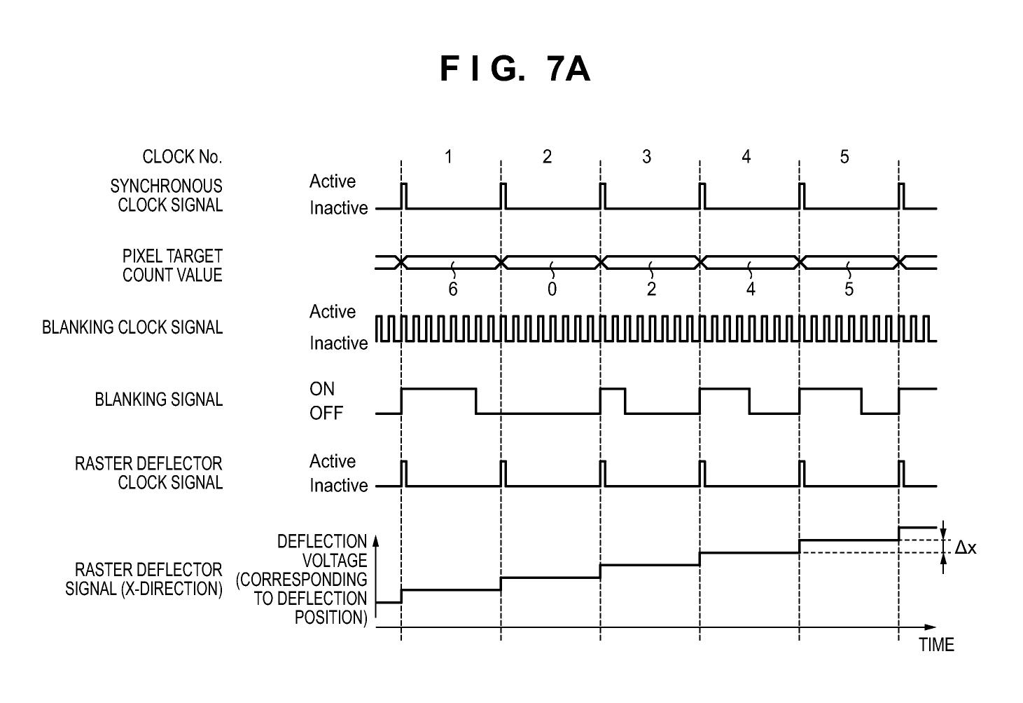

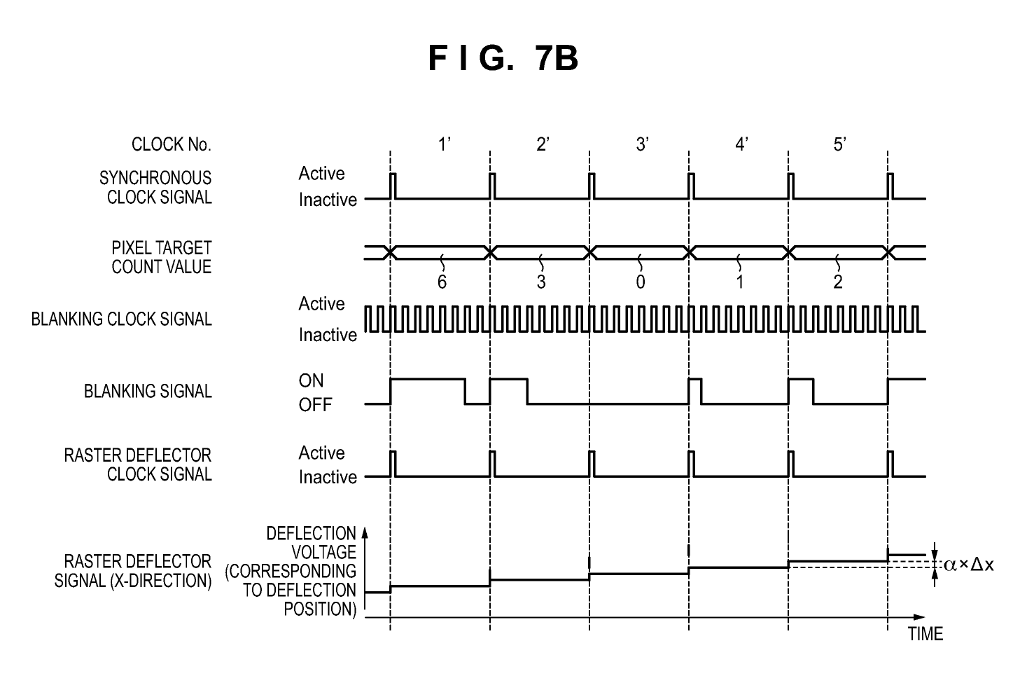

FIGS. 7A and 7B are timing charts when the resist sensitivity D (and/or minimum current density Jmin) has changed, and the deflection speed conversion coefficient α is ½. The definition of the coordinate axes in FIGS. 7A and 7B is the same as in FIGS. 3 and 6. FIG. 7A is a timing chart before the resist sensitivity D (and/or minimum current density Jmin) changes, and FIG. 7B is a timing chart after the resist sensitivity D (and/or minimum current density Jmin) changes. As can be seen from FIGS. 7A and 7B, the deflection speed of the raster deflector 220 has changed by a factor of α (=½). Also, referring to FIGS. 7A and 7B, the pixel target count value is different before and after a change in resist sensitivity D (and/or minimum current density Jmin). This is because due to a change in deflection speed of the raster deflector 220, the pixel size becomes different from that of the drawing data stored in the bitmap memory 113, so the data becomes excessive or insufficient. Hence, in reading out the drawing data from the bitmap memory 113, the energy amount command generation circuit 104 calculates the pixel target count value at the corresponding deflection position using an algorithm for linear interpolation, based on the value of the drawing data in an adjacent pixel.

Calculation of the pixel target count value in FIG. 7B will be explained in more detail below by taking linear interpolation as an example. A point y_new on the Y-axis at a point x_new on the X-axis on a straight line which passes through two points: coordinate positions (x0, y0) and (x1, y1) in a two-dimensional coordinate system is expressed by linear interpolation as:

(y_new−y0)/(y1−y0)=(x_new−x0)/(x1−x0) (9)

To apply equation (9) to FIG. 7B, the point on the X-axis in equation (9) is set in correspondence with the deflection voltage of the raster deflector signal, and the point on the Y-axis in equation (9) is set in correspondence with the pixel target count value.

Referring to FIG. 7A, let x_{—}1 be the deflection voltage (corresponding to the deflection position) of the raster deflector signal for clock No. 1, and x_{—}2 and x_{—}3 be the deflection voltages of the raster deflector signals for clock Nos. 2 and 3, respectively. The drawing position on the substrate 222 in the stage scanning direction is the same in FIGS. 7A and 7B. The deflection speed of the raster deflector 220 in FIG. 7B is half that in FIG. 7A. Hence, when the deflection voltage of the raster deflector signal for clock No. 1′ in FIG. 7B is x_{—}1, those of the raster deflector signals for clock Nos. 3′ and 5′ in FIG. 7B are x_{—}2 and x_{—}3, respectively. A deflection voltage x_{—}1_{—}2 of the raster deflector signal for clock No. 2′ in FIG. 7B satisfies a relation:

x_{—}1_{—}2=(x_{—}1+x_{—}2)/2 (10)

Also, a deflection voltage x_{—}2_{—}3 of the raster deflector signal for clock No. 4′ in FIG. 7B satisfies a relation:

x_{—}2_{—}3=(x_{—}2+x_{—}3)/2 (11)

Calculation of the pixel target count value in FIG. 7B will be explained below. The deflection voltage of the raster deflector signal for clock No. 1′ in FIG. 7B is x^{—}1, which is equal to that of the raster deflector signal for clock No. 1 in FIG. 7A. Hence, the pixel target count value for clock No. 1′ is six, which is equal to that for clock No. 1 in FIG. 7A. The pixel target count values for clock Nos. 3′ and 5′ in FIG. 7B are zero and two, respectively, for the same reason as in the case of clock No. 1′.

A pixel target count value for clock No. 2′ in FIG. 7B can be calculated by substituting a value defined as:

x0=x_{—}1, y0=6, x1=x_{—}2, y1=0, x_new=x_{—}1_{—}2=(x_{—}1+x_{—}2)/2

into equation (9), and solving this equation for y_new. As a result, y_new=3 is obtained. Hence, the pixel target count value for clock No. 2′ in FIG. 7B is three.

A pixel target count value for clock No. 4′ in FIG. 7B is similarly calculated by substituting a value defined as:

x0=x_{—}2, y0=0, x1=x_{—}3, y1=2, x_new=x_{—}2_{—}3=(x_{—}2+x_{—}3)/2

into equation (9), and solving this equation for y_new. As a result, y_new=1 is obtained. Hence, the pixel target count value for clock No. 4′ in FIG. 7B is one.

Subsequent pixel target count values can be calculated in the same way. Although the case wherein the deflection speed conversion coefficient α is ½ has been described with reference to FIGS. 7A and 7B, the pixel target count value can be calculated by linear interpolation in all cases as long as the deflection speed conversion coefficient α is a real number. Also, this calculation operation need not always be performed using linear interpolation, and may be performed by interpolation using a second- or higher-order polynomial.

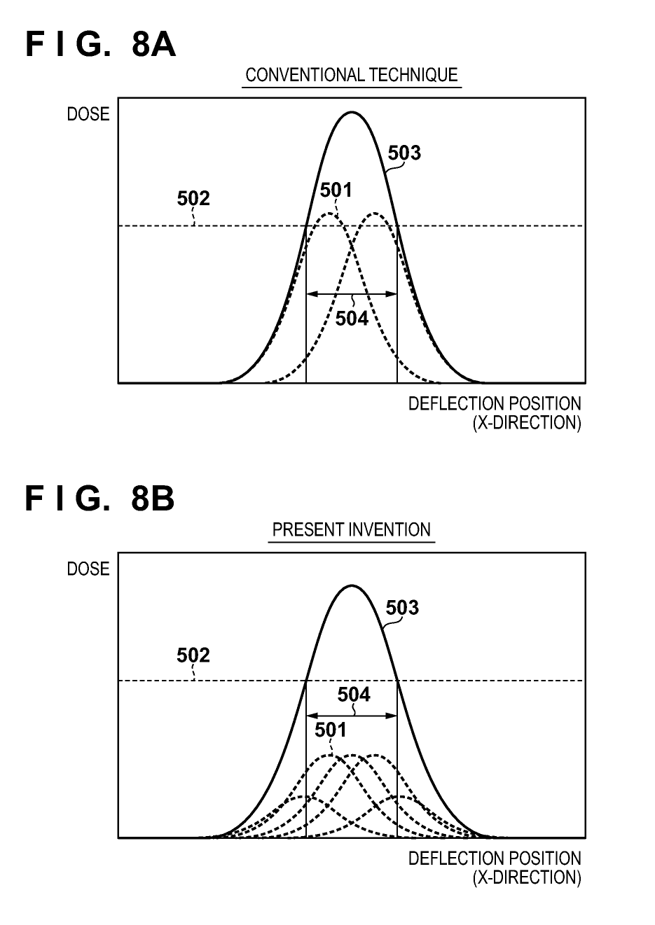

FIGS. 8A and 8B are graphs showing that the cumulative dose distribution of the electron beam is nearly the same in the conventional technique and the present invention when the resist sensitivity D (and/or minimum current density Jmin) has changed. FIGS. 8A and 8B show the exposure results when the maximum irradiation time Tmax (=D/Jmin) has become double the period Tclk of the synchronous clock signal of the synchronous clock signal. FIG. 8A illustrates the cumulative dose distribution of the electron beam in the conventional drawing method, and FIG. 8B illustrates the cumulative dose distribution of the electron beam in the method according to the present invention. In the conventional drawing method, the period of the synchronous clock signal coincides with the maximum irradiation time Tmax. As a result, the period of the blanking clock signal, and the raster deflector clock signal also change.

FIGS. 8A and 8B show the X-coordinate of the deflection position on the abscissa, and the dose on the ordinate. A cumulative dose distribution 503 generated by a plurality of electron beams is obtained by accumulating a dose distribution 501 of each electron beam. The width of the cumulative dose distribution 503 of a plurality of electron beams at a given dose threshold 502 is equal to a line width 504 obtained when exposure is actually performed. The maximum dose of one electron beam in FIG. 8B is half that in FIG. 8A. This is because the period of the synchronous clock signal is not matched with that of the maximum irradiation time. Instead, the deflection speed of the raster deflector 220 halves, so the irradiation pitch of the electron beam halves. The dose of each electron beam is determined using the linear interpolation presented in equation (9). As can be seen from a comparison between FIGS. 8A and 8B, almost the same line width 504 as in the conventional drawing method is obtained in the method according to the present invention.

Two cases: the case wherein only the pixel density Pdata of the drawing data is different from the reference pixel density Pinit, and that wherein the resist sensitivity D of the substrate 222 (and/or the minimum current density Jmin) has changed have been described above. However, the deflection speed of the raster deflector 220 can be calculated using the above-mentioned method even when the pixel density Pdata of the drawing data has changed for the reference pixel density Pinit, and the resist sensitivity D and the minimum current density Jmin among the current densities of all electron beams have also changed. This allows high-precision drawing on the substrate 222. Alternatively, the deflection speed of the raster deflector 220 may be calculated by focusing attention on one of the three pieces of information: the resist sensitivity D, the minimum current density Jmin among the current densities of all electron beams, and the pixel density Pdata of the drawing data while the remaining two pieces of information stay the same.

### Second Embodiment

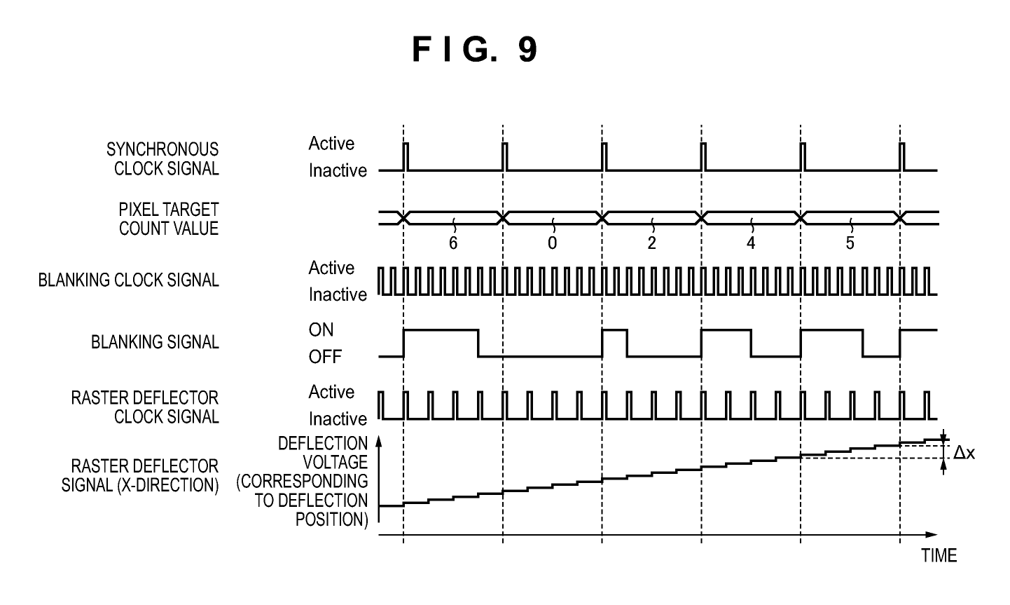

In the first embodiment, the period of the synchronous clock signal coincides with that of the raster deflector clock signal. However, these two periods need not always coincide with each other, and the raster deflector clock signal may be generated by multiplying or dividing the synchronous clock signal. FIG. 9 is a timing chart when the raster deflector clock signal is obtained by multiplying the synchronous clock signal by a factor of four.

In the timing chart as shown in FIG. 9 as well, high-precision drawing can be performed in accordance with the flowchart shown in FIG. 4, even when the resist sensitivity D, the minimum current density Jmin, or the pixel density Pdata of the bitmap drawing data has changed. High-precision drawing can be performed even when the raster deflector signal has an approximately ramp waveform as the period of the raster deflector clock signal is set shorter than that shown in FIG. 9.

[Method of Manufacturing Article]

A method of manufacturing an article according to an embodiment of the present invention is suitable for manufacturing various articles including a microdevice such as a semiconductor device and an element having a microstructure. This method can include a step of forming a latent image pattern on a photosensitive agent, applied on a substrate, using the above-mentioned drawing apparatus (a step of performing drawing on a substrate), and a step of developing the substrate having the latent image pattern formed on it in the forming step. This method can also include subsequent known steps (for example, oxidation, film formation, vapor deposition, doping, planarization, etching, resist removal, dicing, bonding, and packaging). The method of manufacturing an article according to this embodiment is more advantageous in terms of at least one of the performance, quality, productivity, and manufacturing cost of an article than the conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-023506 filed Feb. 6, 2012, which is hereby incorporated by reference herein in its entirety.

What is claimed is:

1. A drawing apparatus which performs drawing on a substrate with a plurality of charged particle beams, the apparatus comprising:
a blanking device configured to individually blank the plurality of charged particle beams;
a scanning deflector configured to deflect the plurality of charged particle beams to scan the plurality of charged particle beams on the substrate; and
a controller configured to generate a periodic signal to control a periodic deflection operation of the plurality of charged particle beams by the scanning deflector,
wherein the controller is configured to adjust an amount of deflection of the plurality of charged particle beams by the scanning deflector in a period of the periodic signal so that a scanning speed of the plurality of charged particle beams becomes a target speed.

2. The apparatus according to claim 1, wherein the controller is configured to determine the target speed based on at least one of a sensitivity of a resist included in the substrate, a current density of the plurality of charged particle beams, and a pixel density of drawing data.

3. The apparatus according to claim 1, wherein the controller is configured to determine the target speed based on a current density of a charged particle beam having a minimum current density among the plurality of charged particle beams.

4. A method of manufacturing an article, the method comprising:
performing drawing on a substrate using a drawing apparatus;
developing the substrate on which the drawing has been performed; and
processing the developed substrate to manufacture the article,
wherein the drawing apparatus performs the drawing on the substrate with a plurality of charged particle beams, the apparatus including:
a blanking device configured to individually blank the plurality of charged particle beams;
a scanning deflector configured to deflect the plurality of charged particle beams to scan the plurality of charged particle beams on the substrate; and
a controller configured to generate a periodic signal to control a periodic deflection operation of the plurality of charged particle beams by the scanning deflector,
wherein the controller is configured to adjust an amount of deflection of the plurality of charged particle beams by the scanning deflector in a period of the periodic signal so that a scanning speed of the plurality of charged particle beams becomes a target speed.
